(19) United States
(12) Patent Application Publication
(10) Pub. No.: US 2025/0048843 A1
(43) Pub. Date: Feb. 6, 2025

(54) DISPLAY DEVICE AND METHOD FOR MANUFACTURING THE SAME

(71) Applicant: Samsung Display Co., Ltd., Yongin-Si (KR)

(72) Inventors: Seok Hyun LIM, Yongin-si (KR); Mi Yeon CHO, Yongin-si (KR); Eun Ho SONG, Yongin-si (KR); Ju Won YOON, Yongin-si (KR); Jae Been LEE, Yongin-si (KR)

(21) Appl. No.: 18/671,787

(22) Filed: May 22, 2024

(30) Foreign Application Priority Data
Aug. 2, 2023 (KR) 10-2023-0100978

(51) Int. Cl. H10K 59/122; G09G 3/3258; H10K 59/12; H10K 59/131

(52) U.S. Cl. CPC H10K 59/122; H10K 59/1201; H10K 59/131; G09G 3/3258; G09G 2300/0819; G09G 2300/0842; G09G 2300/0861; G09G 2320/0209

(57) ABSTRACT

According to an embodiment, a display device may include a semiconductor wafer substrate, a complementary metal oxide semiconductor (CMOS) circuit layer disposed on the semiconductor wafer substrate, and a light emitting element layer disposed on the CMOS circuit layer. The light emitting element layer may include a pixel defining film partitioning a plurality of pixels, a pixel electrode disposed independently in each of the plurality of pixels, an aging wiring disposed between the plurality of pixels, a light emitting layer commonly covering the pixel electrodes of each of the plurality of pixels and the aging wiring, and a common electrode covering the light emitting layer. A portion positioned between the aging wiring and the common electrode of the light emitting layer may include an aged portion in which at least a portion of a conductive layer included in the light emitting layer is aged.

### CROSS-REFERENCE TO RELATED APPLICATION

This application claims priority from Korean Patent Application No. 10-2023-0100978 filed on Aug. 2, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device and method for manufacturing the same.

### 2. Description of the Related Art

A wearable device that is developed in the form of glasses or a helmet and focuses on a distance close to the user's eyes is being developed. For example, the wearable device may be a head mounted display (HMD) device or AR glass. Such a wearable device provides a user with an augmented reality (hereinafter, referred to as “AR”) screen or a virtual reality (hereinafter, referred to as “VR”) screen.

The wearable device such as the HMD device or the AR glass requires a display specification of at least 2000 pixels per inch (PPI) to allow the user to use the device for a long time without feeling dizzy. To this end, organic light emitting diode on silicon (OLEDoS) technology, which is a small organic light emitting display device with high resolution, is emerging. The OLEDoS is a technology that disposes organic light emitting diodes (OLEDs) on a semiconductor wafer substrate on which a complementary metal oxide semiconductor (CMOS) is disposed.

Since a distance between pixels is reduced in a display panel to which the OLEDoS technology has been applied, an unintended leakage current may be generated between adjacent pixels. The leakage current may be generated through some conductive layers of a light emitting layer disposed between a pixel electrode (e.g., an anode) and a common electrode (e.g., cathode). The leakage current is known to be a cause of color crosstalk between adjacent pixels.

### SUMMARY

Aspects of the present disclosure provide a display device capable of preventing color interference (color crosstalk) between adjacent pixels by preventing leakage current between adjacent pixels, and a method for manufacturing the same.

According to an embodiment of the present disclosure, a display device may include a semiconductor wafer substrate, a complementary metal oxide semiconductor (CMOS) circuit layer disposed on the semiconductor wafer substrate, and a light emitting element layer disposed on the CMOS circuit layer. The light emitting element layer may include a pixel defining film partitioning a plurality of pixels, a pixel electrode disposed independently in each of the plurality of pixels, an aging wiring disposed between the plurality of pixels, a light emitting layer commonly covering the pixel electrodes of each of the plurality of pixels and the aging wiring, and a common electrode covering the light emitting layer. A portion positioned between the aging wiring and the common electrode of the light emitting layer may include an aged portion in which at least a portion of a conductive layer included in the light emitting layer is aged.

The aged portion of the light emitting layer has a higher resistance of the conductive layer compared to other portions of the light emitting layer.

The pixel defining film may include a first opening in which the pixel electrode is disposed, and a second opening and a third opening in which the aging wiring is disposed.

The aging wiring may include a first aging wiring disposed in the second opening to cross between each column of the plurality of pixels, and a second aging wiring disposed in the third opening to cross between each row of the plurality of pixels.

The aging wiring may have a mesh shape in which the first aging wiring and the second aging wiring are on the same layer.

The first aging wiring and the second aging wiring may be disposed on a same layer as the pixel electrode.

The first aging wiring and the second aging wiring may be disposed on different layers.

The first aging wiring may be disposed on a different layer from the pixel electrode, and the second aging wiring may be disposed on a same layer as the pixel electrode.

Each of the first aging wiring and the second aging wiring may include a pair of wirings arranged at intervals from each other between adjacent pixels.

At least some conductive layers included in the light emitting layer may include at least one layer among a charge generation layer, a hole injection layer, a hole transport layer, an electron transport layer, and a p-doped layer.

According to an embodiment of the present disclosure, a method of manufacturing a display device may include forming a complementary metal oxide semiconductor (CMOS) circuit layer on a semiconductor wafer substrate, forming a light emitting element layer including a pixel electrode, a light emitting layer, and a common electrode on the CMOS circuit layer, and aging at least some conductive layers included in the light emitting layer by supplying a designated voltage to an aging wiring disposed between a plurality of pixels during designated time. The at least some conductive layers have an increased resistance due to the aging between the plurality of pixels.

The forming of the light emitting element layer may include forming a pixel defining film partitioning the plurality of pixels. The pixel defining film may include a first opening in which the pixel electrode is disposed, and a second opening and a third opening in which the aging wiring is disposed.

The aging wiring may include a first aging wiring disposed in the second opening to cross between each column of the plurality of pixels, and a second aging wiring disposed in the third opening to cross between each row of the plurality of pixels.

The aging wiring may have a mesh shape in which the first aging wiring and the second aging wiring are formed on a same layer.

The method of manufacturing the display device may include forming the first aging wiring and the second aging wiring on a same layer as the pixel electrode.

The first aging wiring and the second aging wiring may be disposed on different layers.

The first aging wiring may be disposed on a different layer from the pixel electrode, and the second aging wiring may be disposed on the same layer as the pixel electrode.

Each of the first aging wiring and the second aging wiring may include a pair of wirings arranged at intervals from each other between adjacent pixels.

The at least some conductive layers included in the light emitting layer may include at least one layer among a charge generation layer, a hole injection layer, a hole transport layer, an electron transport layer, and a p-doped layer.

The designated voltage supplied to the aging wiring may be approximately 50V.

In accordance with the display device and the method of manufacturing the same according to embodiments, leakage current and color crosstalk between adjacent pixels can be prevented by aging some conductive layers of a light emitting layer disposed between adjacent pixels.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

These and/or other aspects will become apparent and more readily appreciated from the following description of the embodiments, taken in conjunction with the accompanying drawings.

FIG. 1 is a perspective view of a display device according to an embodiment.

FIG. 2 is a plan view of a display panel according to an embodiment.

FIG. 3 is a configuration block diagram of the display device according to an embodiment.

FIG. 4 is a circuit diagram of a pixel of the display device according to an embodiment.

FIG. 5 is a schematic cross-sectional view of a portion of the display panel of the display device according to an embodiment.

FIG. 6 is a cross-sectional view schematically illustrating the structure of a light emitting element according to an embodiment.

FIGS. 7, 8, 9, and 10 are cross-sectional views illustrating the structures of light emitting elements according to an embodiment.

FIG. 11 is a cross-sectional view illustrating an example of an organic light emitting diode of FIG. 9.

FIG. 12 is a cross-sectional view illustrating an example of an organic light emitting diode of FIG. 10.

FIG. 13 is a cross-sectional view illustrating a structure of a pixel of a display device according to an embodiment.

FIG. 14 is a plan view schematically illustrating a portion of a pixel of a display panel according to an embodiment.

FIG. 15 is a diagram illustrating a portion of a cross-section of a display panel taken along line A-A′ of FIG. 14.

FIG. 16 is a plan view of a display panel illustrating an example in which a pair of aging wirings is disposed between the pixels.

FIG. 17 is a diagram illustrating a portion of a cross-section of a display panel taken along line B-B′ of FIG. 16.

FIG. 18 is a plan view of a display panel illustrating an example in which an aging wiring is disposed on a pixel defining film.

FIG. 19 is a plan view of a display panel illustrating an example in which an aging wiring is not formed in a mesh structure.

FIG. 20 is a flowchart illustrating a method for manufacturing a display device according to an embodiment.

FIG. 21 is an example view of a VR device including a display device according to an embodiment.

FIGS. 22 and 23 are exemplary views illustrating an HMD device to which the display device according to an embodiment is applied.

### DETAILED DESCRIPTION OF THE EMBODIMENTS

The inventive concept will now be described more fully hereinafter with reference to the accompanying drawings, in which embodiments of the inventive concept are shown. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the inventive concept. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

Hereinafter, specific embodiments will be described with reference to the accompanying drawings.

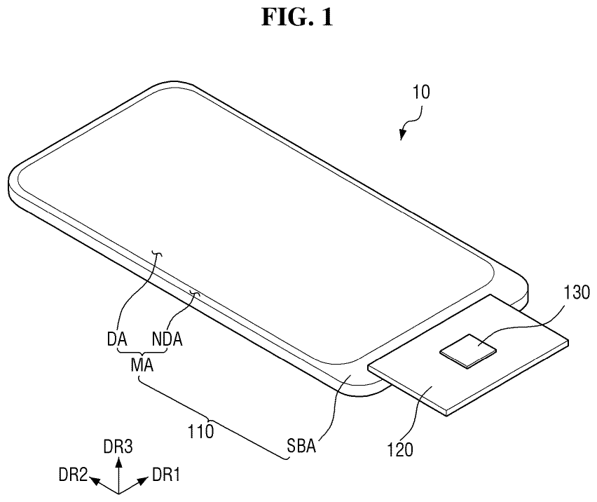

FIG. 1 is a perspective view of a display device 10 according to an embodiment.

Referring to FIG. 1, the display device 10 may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 may be applied as a display unit of a television, a notebook computer, a monitor, a billboard, or an Internet of things (IoT) device. For another example, the display device 10 may be applied to wearable devices such as smart watches, watch phones, glasses-type displays, and head mounted displays (HMDs).

The display device 10 may have a planar shape similar to a quadrangle. For example, the display device 10 may have a planar shape similar to a quadrangle having short sides in a first direction DR1 and long sides in a second direction DR2. Alternatively, the display device 10 may have a planar shape similar to a quadrangle having long sides in the first direction DR1 and short sides in the second direction DR2. In FIG. 1, a third direction DR3 represents a normal direction perpendicular to a plane defined by the first direction DR1 and the second direction DR2. Each corner where a short side meets a long side may be rounded with a predetermined curvature or may be right-angled. The planar shape of the display device 10 is not limited to a quadrangular shape but may also be similar to other polygonal shapes, a circular shape, or an elliptical shape.

The display device 10 includes a display panel 110, a circuit board 120, and a power supply unit 130.

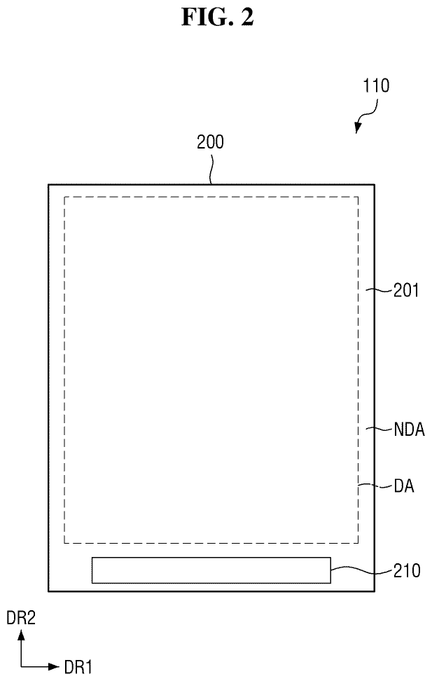

The display panel 110 uses a semiconductor wafer substrate (200 in FIG. 2) as a base substrate. The display panel 110 may include a main area MA and a sub-area SBA.

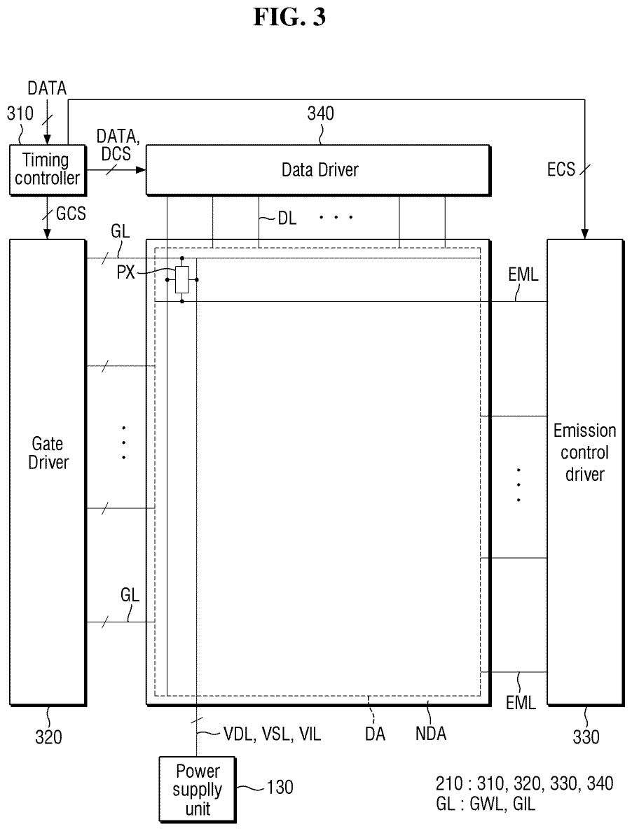

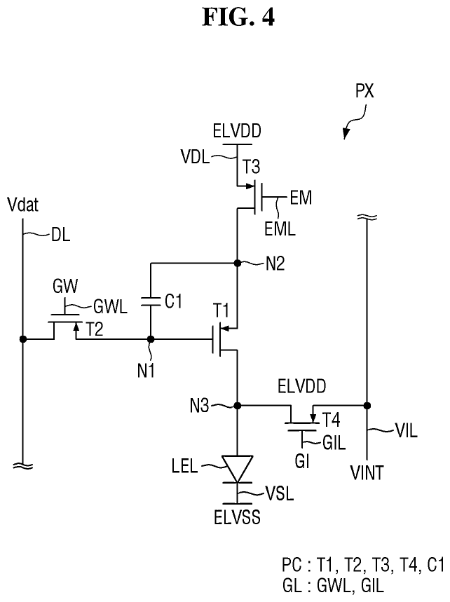

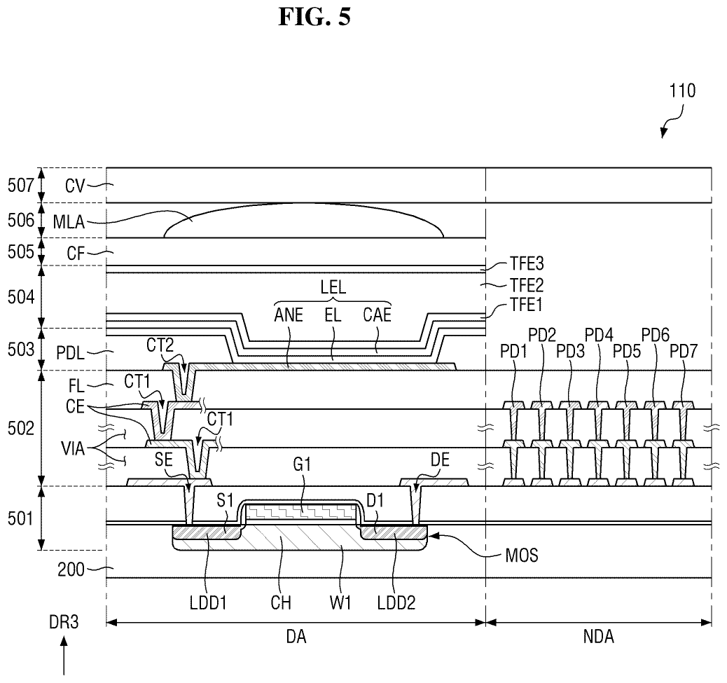

The main area MA may include a display area DA including pixels PX in FIG. 3 displaying an image, and a non-display area NDA disposed around the display area DA. The non-display area NDA may refer to an area other than the display area DA. The display area DA may emit light from a plurality of light emitting areas or a plurality of opening areas. For example, the display panel 110 may include a pixel driving circuit PC in FIG. 4 including switching elements, a pixel defining film PDL in FIG. 5 defining a light emitting area or an opening area, and a light emitting element LEL in FIG. 5 that is a self-light emitting element.

The light emitting elements LEL may include, but are not limited to, at least one of an organic light emitting diode including an organic light emitting layer, a quantum dot light emitting diode including a quantum dot light emitting layer, an inorganic light emitting diode including an inorganic semiconductor, and a micro-light emitting diode.

The non-display area NDA may be an area outside the display area DA. The non-display area NDA may be defined as an edge area of the main area MA of the display panel 110. The non-display area NDA may include fan-out lines (not illustrated) extending from lines (e.g., gate lines, data lines, and emission control lines) of the display area DA and a display pad unit (not illustrated).

The sub-area SBA may extend from a side of the main area MA. The sub-area SBA may include a main pad unit connected to the circuit board 120. Optionally, the sub-area SBA may be omitted, and the main pad unit may be disposed in the non-display area NDA.

The circuit board 120 may be attached onto the main pad unit of the display panel 110 using an anisotropic conductive film (ACF). Lead lines of the circuit board 120 may be electrically connected to the main pad unit of the display panel 110. The circuit board 120 may be a flexible printed circuit board, a printed circuit board, or a flexible film such as a chip on film.

The power supply unit 130 may be disposed on the circuit board 120, and may supply a power voltage to a display driving circuit 210 (see FIG. 2) and the display panel 110. The power supply unit 130 may generate a driving voltage and supply the driving voltage to a driving voltage line. For example, the driving voltage may include a high-potential voltage (see a first driving voltage, ELVDD in FIG. 4 for example), a low-potential voltage (see a second driving voltage, ELVSS in FIG. 4 for example), and an initialization voltage VINT in FIG. 4 for driving the light emitting element LEL.

FIG. 2 is a plan view of a display panel 110 according to an embodiment.

Referring to FIG. 2, the display panel 110 may be an organic light emitting diode on silicon (OLEDoS) panel using a semiconductor wafer substrate 200 as a base substrate. For example, the display panel 110 may include the semiconductor wafer substrate 200, and the pixel driving circuit PC in FIG. 4 and the display driving circuit 210 controlling the pixel driving circuit PC may be disposed on a front surface 201 of the semiconductor wafer substrate 200. The pixel driving circuit PC is disposed to overlap the light emitting element LEL in FIG. 5 of each pixel PX in FIG. 3 in the display area DA. The display driving circuit 210 is disposed in the non-display area NDA and serves to drive the pixel driving circuits PC.

The pixel driving circuit PC in FIG. 4 and the display driving circuit 210 may be formed on a metal oxide semiconductor field effect transistor (MOSFET) layer 501 (see FIG. 5) disposed on the front surface 201 of the semiconductor wafer substrate 200. The MOSFET layer 501 may include, for example, an N-type MOSFET and/or a P-type MOSFET.

FIG. 3 is a configuration block diagram of the display device 10 according to an embodiment.

Referring to FIG. 3, the display device 10 includes a display panel 110 based on the semiconductor wafer substrate 200 (see FIG. 2). The display driving circuit 210 is embedded in the display panel 110. The display driving circuit 210 is formed on the MOSFET layer 501 (see FIG. 5) disposed on the front surface of the semiconductor wafer substrate 200. The display driving circuit 210 may include a timing controller 310, a gate driver 320, an emission control driver 330, and a data driver 340, but the present disclosure is not limited thereto. Although not illustrated, the display driving circuit 210 may further include a memory (e.g., OTP), an interface circuit (e.g., I/F), an image processing circuit (e.g., Logic), and/or a gamma processing circuit.

The display area DA of the display panel 110 includes a plurality of pixels PX disposed in a matrix form. Each of the plurality of pixels PX may be connected to a first driving voltage line VDL, a second driving voltage line VSL, a gate line GL, an emission control line EML, an initialization line VIL, and a data line DL.

The first driving voltage line VDL supplies the first driving voltage ELVDD in FIG. 4 input from the power supply unit 130 to the plurality of pixels PX. The second driving voltage line VSL supplies the second driving voltage ELVSS in FIG. 4 input from the power supply unit 130 to the plurality of pixels PX. The gate line GL supplies gate signals GI and GW in FIG. 4 input from the gate driver 320 to the plurality of pixels PX. The emission control line EML supplies an emission control signal EM in FIG. 4 input from the emission control driver 330 to the plurality of pixels PX. The initialization line VIL supplies the initialization voltage VINT in FIG. 4 input from the power supply unit 130 to the plurality of pixels PX. The data line DL supplies analog data voltages input from the data driver 340 to the pixels PX.

The first driving voltage ELVDD may be a high-potential voltage, and the second driving voltage ELVSS may be a low-potential voltage. For example, the first driving voltage ELVDD may have a potential higher than that of the second driving voltage ELVSS. The initialization voltage VINT in FIG. 4 may have a potential for initializing the pixel driving circuit (PC in FIG. 4 for each frame.

One gate line GL illustrated in FIG. 3 may include a first gate line GWL and a second gate line GIL, but the present disclosure is not limited thereto.

Each of the plurality of pixels PX includes the light emitting element LEL in FIG. 4, and may include a plurality of transistors and one or more capacitors as the pixel driving circuit PC in FIG. 4 for driving the light emitting element LEL.

The timing controller 310 may receive a data signal DATA and timing signals from the circuit board 120. The timing controller 310 may control an operation timing of the data driver 340 by generating a data control signal DCS based on the timing signals. The timing controller 310 may control an operation timing of the gate driver 320 by generating a gate control signal GCS based on the timing signals. The timing controller 310 may control an operation timing of the emission control driver 330 by generating an emission control signal ECS based on the timing signals.

The data driver 340 may convert the data signal DATA into analog data voltages and supply the converted analog data voltages to the pixels PX through the data lines DL. The gate signals of the gate driver 320 may select the pixels PX to which the data voltage is supplied, and the selected pixels PX may receive the data voltage through the data lines DL.

The power supply unit 130 may be disposed on the circuit board 120 (see FIG. 1), and may supply a power voltage to the display driving circuit 210 and the display panel 110. The power supply unit 130 may generate a driving voltage and supply the driving voltage to the driving voltage line VDL, and may generate a common voltage and supply the common voltage to a common electrode (e.g., a common electrode CAE in FIG. 5) common to the light emitting elements LEL of the plurality of pixels.

The gate driver 320 may supply the gate signals GI and GW in FIG. 4 to the pixels PX through the gate lines GL.

The emission control driver 330 may supply the emission signal EM in FIG. 4 to the pixels PX through the emission control lines EML.

FIG. 4 is a circuit diagram of a pixel PX of the display device according to an embodiment.

Referring to FIG. 4, the pixel PX may include the light emitting element LEL (e.g., an organic light emitting diode) as a display element and the pixel driving circuit PC connected to the light emitting element LEL. The pixel driving circuit PC may include first to fourth transistors T1, T2, T3, and T4 and a first capacitor C1, but the present disclosure is not limited thereto. The first to fourth transistors T1, T2, T3, and T4 may be implemented as N-type metal oxide semiconductor field effect transistors (MOSFETs) and/or P-type MOSFETs. It is illustrated in FIG. 4 that the first to fourth transistors T1, T2, T3, and T4 are P-type MOSFETs, but the present disclosure is not limited thereto.

The first transistor T1 may be a driving transistor whose source-drain current is determined according to a gate-source voltage, and each of the second to fourth transistors T2 to T4 may be a switching transistor that is turned on/off according to a gate-source voltage, substantially a gate voltage.

The first transistor T1 includes a gate connected to a first node N1, a source connected to a second node N2, and a drain connected to a third node N3. The first transistor T1 is turned on or off based on a voltage level of the first node N1. The turned-on first transistor T1 connects the second node N2 and the third node N3. The second node N2 is a node connected to a source of the third transistor T3, and is a node to which the first driving voltage ELVDD is supplied when the third transistor T3 is turned on in response to the emission control signal EM. The third node N3 is a node to which a pixel electrode ANE in FIG. 5 of the light emitting element LEL and a drain of the fourth transistor T4 are connected. The third node N3 is a node to which the initialization voltage VINT is supplied when the fourth transistor T4 is turned on in response to the second gate signal GI.

The second transistor T2 includes a gate connected to the first gate line GWL, a source connected to the data line DL, and a drain connected to the first node N1. The second transistor T2 is turned on in response to the first gate signal GW supplied from the first gate line GWL. The turned-on second transistor T2 supplies a data signal Vdat supplied from the data line DL to the first node N1.

The third transistor T3 includes a gate connected to the emission control line EML, a source connected to the first driving voltage line VDL to which the first driving voltage ELVDD is supplied, and a drain connected to the second node N2. The third transistor T3 is turned on in response to the emission control signal EM supplied from the emission control line EML. The turned-on third transistor T3 supplies the first driving voltage ELVDD to the second node N2.

The fourth transistor T4 includes a gate connected to the second gate line GIL, a source connected to the initialization line VIL to which the initialization voltage VINT is supplied, and a drain connected to the third node N3. The fourth transistor T4 is turned on in response to the second gate signal GI supplied from the second gate line GIL. The turned-on fourth transistor T4 supplies the initialization voltage VINT to the third node N3.

The first capacitor C1 is disposed between the first node N1 and the second node N2. The first capacitor C1 serves to store the data signal Vdat input through the second transistor T2.

The light emitting element LEL may include a pixel electrode (e.g., the pixel electrode ANE in FIG. 5) and a common electrode (e.g., the common electrode CAE in FIG. 5) facing the pixel electrode, and the common electrode may be applied with the second driving voltage ELVSS. The common electrode may be connected to the second driving voltage line VSL transmitting the second driving voltage ELVSS. The common electrode may be commonly connected to the plurality of pixels PX.

FIG. 5 is a schematic cross-sectional view of a portion of the display panel 110 of the display device according to an embodiment. For example, FIG. 5 is a view schematically illustrating a stacked structure of each of the non-display area NDA and the display area DA of the display panel 110 according to an embodiment.

In the description with reference to FIG. 5, the expression “on” may mean a third direction toward which the front surface of the semiconductor wafer substrate 200 faces. The front surface of the semiconductor wafer substrate 200 may refer to a direction in which light emitting elements LEL disposed in the display area DA emit light for displaying an image.

Referring to FIG. 5, the display panel 110 uses the semiconductor wafer substrate 200 as a base substrate. A MOSFET layer 501 including the display driving circuit 210 and the pixel driving circuit PC (see FIGS. 2-3), at least one wiring layer 502, the light emitting element layer 503 including the light emitting element LEL, an encapsulation layer 504 covering the light emitting element LEL, a color filter layer 505 including a color filter CF, a light control layer 506 including a refractive film MLA, and a protective layer 507 including a cover glass CV may be sequentially stacked on the front surface of the semiconductor wafer substrate 200. At least some of the light emitting element layer 503, the encapsulation layer 504, the color filter layer 505, the light control layer 506, and the protective layer 507 may not be disposed in the non-display area NDA.

The semiconductor wafer substrate 200 may be a silicon substrate, a germanium substrate, or a silicon-germanium substrate. The semiconductor wafer substrate 200 may be a substrate doped with first-type impurities.

The MOSFET layer 501 including an N-type MOSFET and/or a P-type MOSFET is disposed on the semiconductor wafer substrate 200. The first type impurity may be a P-type impurity, and the second type impurity may be an N-type impurity. Alternatively, the first type impurity may be an N-type impurity, and the second type impurity may be a P-type impurity.

Herein, an N-type MOSFET MOS included in the MOSFET layer 501 will be described as an example. The N-type MOSFET MOS may include a well region W1 doped with an N-type impurity in a substrate doped with a P-type impurity.

The well region W1 may include a first low-concentration impurity region LDD1 and a second low-concentration impurity region LDD2 having a relatively lower impurity concentration than other portions. The first low-concentration impurity region LDD1 may define a source region S1, and the second low-concentration impurity region LDD2 may define a drain region D1. A source electrode SE of the MOSFET MOS may be connected to the source region S1, and a drain electrode DE of the MOSFET MOS may be connected to the drain region D1.

A channel CH disposed to overlap agate G1 is defined between the first low-concentration impurity region LDD1 and the second low-concentration impurity region LDD2. An oxide film (not illustrated), which is an insulating layer, may be disposed between the gate G1 and the well region W1.

The MOSFETs MOS constitute the display driving circuit 210, and the display driving circuit 210 are disposed in the non-display area NDA of the display panel 110. In addition, the MOSFETs MOS constitute the transistors T1, T2, T3, and T4 in FIG. 4 included in the pixel driving circuit PC, and the pixel driving circuit PC is disposed in the display area DA of the display panel 110. That is, each pixel driving circuit PC is a circuit including a combination of MOSFETs MOS disposed in the MOSFET layer 501 to correspond to the display area DA. In addition, the display driving circuit 210 is a circuit including a combination of MOSFETs MOS disposed in the MOSFET layer 501 to correspond to the non-display area NDA. FIG. 5 exemplarily illustrates one MOSFET MOS of the pixel driving circuit PC disposed in the display area DA of the display panel 110 for convenience of explanation.

At least one wiring layer 502 is disposed on the MOSFET layer 501. At least one wiring layer 502 includes insulating layers VIA sequentially stacked on the MOSFET layer 501, and an electrode CE and a wiring (not illustrated) connected to the MOSFET MOS through contact holes CT1 penetrating through at least a portion of the insulating layers VIA.

The electrodes CE disposed in the wiring layer 502 include a first vertical connection electrode CE for connecting some of the plurality of MOSFETs MOS disposed in the MOSFET layer 501 corresponding to the pixel driving circuit PC and the light emitting element LEL disposed on the wiring layer 502 in a vertical direction. Here, the vertical direction refers to the normal direction DR3 of the display panel 110.

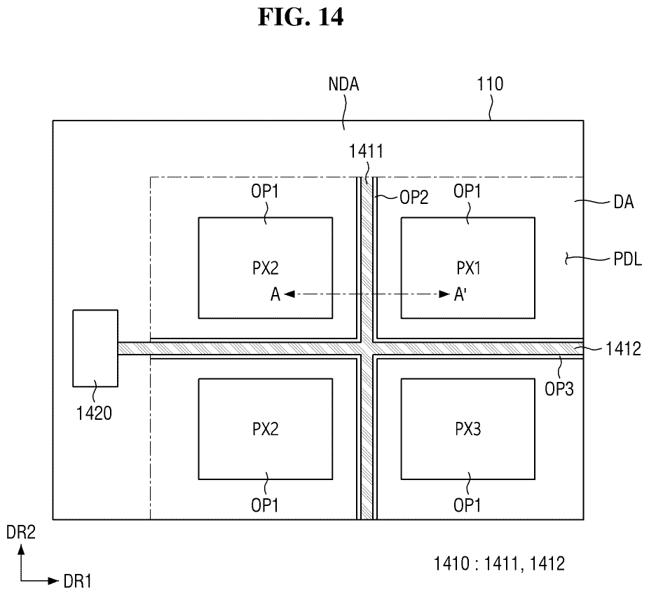

The wirings (not illustrated) disposed in the wiring layer 502 include lines (e.g., lines GL, DL, and EML in FIG. 3) connected to the pixel driving circuit PC. The wirings disposed in the wiring layer 502 further include fan-out lines (not illustrated) extending from the lines (e.g., lines GL, DL, and EML in FIG. 3) connected to the pixel driving circuit PC and disposed in the non-display area NDA. The wirings disposed in the wiring layer 502 may include an aging signal supply wiring (not shown) for delivering an aging signal to aging wirings 1410 in FIG. 14 described later with reference to FIGS. 14 to 19. Meanwhile, the wiring layer 502 may not include an aging signal supply wiring (not shown), in which case the aging wirings 1410 extend from the same layer as the pixel electrode ANE to the non-display area NDA to be connected to an aging pad 1420 in FIG. 14 to which an aging signal is applied.

The term “aging wiring” included in this document may be referred to as “heating wiring” since it performs the function of applying heat to the common layer, or “dummy wiring” since it is not used during the driving period when the display device 10 displays the screen.

The wiring layer 502 may include pad electrodes PD1, PD2, PD3, PD4, PD5, PD6, and PD7 disposed to correspond to the non-display area NDA. The pad electrodes PD1, PD2, PD3, PD4, PD5, PD6, and PD7 may include a first gate pad PD1 to which the first gate line GWL is connected, a second gate pad PD2 to which the second gate line GIL is connected, an initialization pad PD3 to which the initialization line VIL is connected, a light emitting pad PD4 to which the emission control line EML is connected, a data pad PD5 to which the data line DL is connected, a first driving voltage pad PD6 to which the first driving voltage line VDL is connected, and a second driving voltage pad PD7 to which the second driving voltage line VSL is connected. However, the pad electrodes PD1, PD2, PD3, PD4, PD5, PD6, and PD7 illustrated in FIG. 5 are only examples, and the present disclosure is not limited thereto. For example, the wiring layer 502 may further include an aging pad 1420 connected to an aging signal supply wiring (not illustrated) or an aging wiring 1410 in the non-display area NDA. The aging pad 1420 may be electrically connected to the aging wiring 1410 through an aging signal supply wiring, or may be directly connected to the aging wiring 1410.

The light emitting element layer 503 including the light emitting element LEL may be disposed on the at least one wiring layer 502 including a planarization film FL. The light emitting element LEL includes the pixel electrode ANE connected to the first vertical connection electrode CE through a second contact hole CT2 in the planarization film FL and connected to the MOSFET MOS included in the pixel driving circuit PC through the first vertical connection electrode CE, a light emitting layer EL disposed on the pixel electrode ANE, and a common electrode CAE disposed on the light emitting layer EL. The light emitting element layer 503 may further include a pixel defining film PDL that partitions each of the plurality of pixels PX.

The encapsulation layer 504 including at least one organic encapsulation layer and at least one inorganic encapsulation layer may be disposed on the light emitting element layer 503. For example, the encapsulation layer 504 may include a first encapsulation inorganic film TFE1, an encapsulation organic film TFE2, and a second encapsulation inorganic film TFE3, but the present disclosure is not limited thereto.

The color filter layer 505 including a color filter CF may be disposed on the encapsulation layer 504. The color filter CF may include a red color filter that transmits red light, a green color filter that transmits green light, and a blue color filter that transmits blue light, but the present disclosure is not limited thereto. The color filter layer 505 is provided when the light emitting element LEL of the light emitting element layer 503 emits white light. If the light emitting element LEL of the light emitting element layer 503 directly emits red light, green light, and blue light, the color filter layer 505 may be omitted.

The light control layer 506 including the refractive film MLA is disposed on the color filter layer 505. The refractive film MLA may refract incident light so that the light emitted from the light emitting element layer 503 is directed toward the normal direction DR3 of the display panel 110. Such a refractive film MLA may include a micro-lense array.

The protective layer 507 serving as a cover layer may be disposed on the light control layer 506. The protective layer 507 may include the cover glass CV made of glass, but the present disclosure is not limited thereto. The protective layer 507 may include, for example, a protective film.

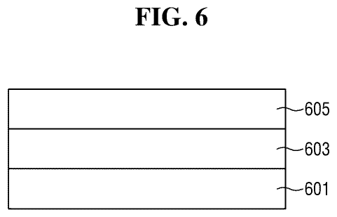

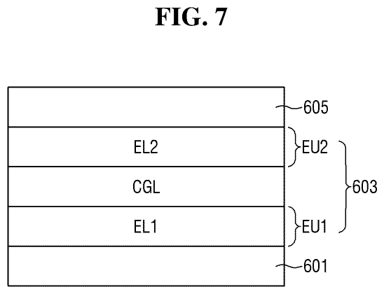

FIG. 6 is a cross-sectional view schematically illustrating the structure of a light emitting element LEL according to an embodiment, and FIGS. 7 to 10 are cross-sectional views illustrating the structures of a light emitting element LEL according to an embodiment.

Referring to FIG. 6, a light emitting element LEL (e.g., an organic light emitting diode) according to an embodiment may include a pixel electrode 601, a common electrode 605, and an intermediate layer 603 between the pixel electrode 601 and the common electrode 605 described above. In the following description, the pixel electrode 601 may refer to the pixel electrode ANE described with reference to FIG. 5. The common electrode 605 may refer to the common electrode CAE described with reference to FIG. 5.

The pixel electrode 601 may include a light-transmitting conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 601 may be a reflective layer including silver (Ag), magnesium (Mg), aluminum (Al), platinum (Pt), palladium (Pd), gold (Au), nickel (Ni), neodymium (Nd), iridium (Ir), chromium (Cr), or compounds thereof. For example, the pixel electrode 601 may have a three-layer structure of ITO/Ag/ITO.

The common electrode 605 may be disposed on the intermediate layer 603. The common electrode 605 may include a metal having a low work function, an alloy, an electrically conductive compound, or any combination thereof. For example, the common electrode 605 may include lithium (Li), silver (Ag), magnesium (Mg), aluminum (Al), aluminum-lithium (Al—Li), calcium (Ca), magnesium-indium (Mg— In), magnesium-silver (Mg—Ag), ytterbium (Yb), silver-ytterbium (Ag—Yb), ITO, IZO, or any combination thereof. The common electrode 605 may be a transmissive electrode, a semi-transmissive electrode, or a reflective electrode.

The intermediate layer 603 may include a high molecular or low molecular organic material emitting light of a predetermined color. The intermediate layer 603 may further include a metal-containing compound such as an organometallic compound, an inorganic material such as quantum dots, and the like, in addition to various organic materials.

In an embodiment, the intermediate layer 603 may include one light emitting layer and a first functional layer and a second functional layer respective disposed below and above the one light emitting layer. The first functional layer may include, for example, a hole transport layer (HTL) or a hole transport layer and a hole injection layer (HIL). The second functional layer is a component disposed on the light emitting layer and is optional. For example, the intermediate layer 603 may or may not include the second functional layer. The second functional layer may include an electron transport layer (ETL) and/or an electron injection layer (EIL).

In an embodiment, the intermediate layer 603 may include two or more light emitting units sequentially stacked between the pixel electrode 601 and the common electrode 605 and a charge generation layer CGL disposed between the two light emitting units. When the intermediate layer 603 includes the light emitting units and the charge generation layer, the light emitting element LEL (e.g., the organic light emitting diode) may be a tandem light emitting element LEL. The light emitting element LEL (e.g., the organic light emitting diode) may improve color purity and luminous efficiency by having a stacked structure of a plurality of light emitting units.

One light emitting unit may include a light emitting layer and a first functional layer and a second functional layer respective disposed below and above the light emitting layer. The charge generation layer CGL may include a negative charge generation layer and a positive charge generation layer. The luminous efficiency of the organic light emitting diode, which is the tandem light emitting element LEL having a plurality of light emitting layers, may be further increased by the negative charge generation layer and the positive charge generation layer.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

In an embodiment, as illustrated in FIG. 7, the light emitting element LEL (e.g., the organic light emitting diode) may include a first light emitting unit EU1 including a first light emitting layer EL1 and a second light emitting unit EU2 including a second light emitting layer EL2 that are sequentially stacked. A charge generation layer CGL may be disposed between the first light emitting unit EU1 and the second light emitting unit EU2. For example, the light emitting element LEL (e.g., the organic light emitting diode) may include the pixel electrode 601, the first light emitting layer EL1, the charge generation layer CGL, the second light emitting layer EL2, and the common electrode 605 that are sequentially stacked. A first functional layer and a second functional layer may be disposed below and above the first light emitting layer EL1, respectively. A first functional layer and a second functional layer may be disposed below and above the second light emitting layer EL2, respectively. The first light emitting layer EL1 may be a blue light emitting layer, and the second light emitting layer EL2 may be a yellow light emitting layer.

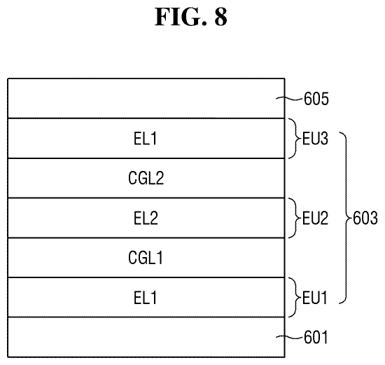

In an embodiment, as illustrated in FIG. 8, the light emitting element LEL (e.g., the organic light emitting diode) may include a first light emitting unit EU1 including a first light emitting layer EL1, a third light emitting unit EU3, and a second light emitting unit EU2 including a second light emitting layer EL2. A first charge generation layer CGL1 may be disposed between the first light emitting unit EU1 and the second light emitting unit EU2, and a second charge generation layer CGL2 may be disposed between the second light emitting unit EU2 and the third light emitting unit EU3. For example, the light emitting element LEL (e.g., the organic light emitting diode) may include the pixel electrode 601, the first light emitting layer EL1, the first charge generation layer CGL1, the second light emitting layer EL2, the second charge generation layer CGL2, the first light emitting layer EL1, and the common electrode 605 that are sequentially stacked. A first functional layer and a second functional layer may be disposed below and above the first light emitting layer EL1, respectively. A first functional layer and a second functional layer may be disposed below and above the second light emitting layer EL2, respectively. The first light emitting layer EL1 may be a blue light emitting layer, and the second light emitting layer EL2 may be a yellow light emitting layer.

In an embodiment, in the light emitting element LEL (e.g., the organic light emitting diode), the second light emitting unit EU2 may further include a third light emitting layer and/or a fourth light emitting layer in direct contact with the second light emitting layer EL2 below and/or above the second light emitting layer EL2 in addition to the second light emitting layer EL2. Here, the phrase “direct contact” may mean that no other layer is disposed between the second light emitting layer EL2 and the third light emitting layer and/or between the second light emitting layer EL2 and the fourth light emitting layer. The third light emitting layer may be a red light emitting layer, and the fourth light emitting layer may be a green light emitting layer.

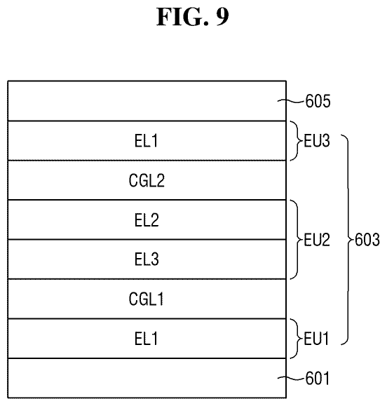

Referring to FIG. 9, the light emitting element LEL (e.g., the organic light emitting diode) may include the pixel electrode 601, the first light emitting layer EL1, the first charge generation layer CGL1, a third light emitting layer EL3, the second light emitting layer EL2, the second charge generation layer CGL2, the first light emitting layer EL1, and the common electrode 605 that are sequentially stacked.

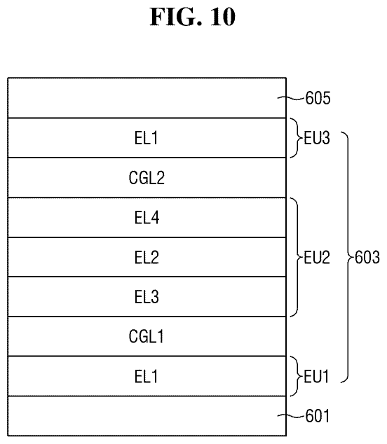

Referring to FIG. 10, the light emitting element LEL (e.g., the organic light emitting diode) may include the pixel electrode 601, the first light emitting layer EL1, the first charge generation layer CGL1, the third light emitting layer EL3, the second light emitting layer EL2, a fourth light emitting layer EL4, the second charge generation layer CGL2, the first light emitting layer EL1, and the common electrode 605 that are sequentially stacked.

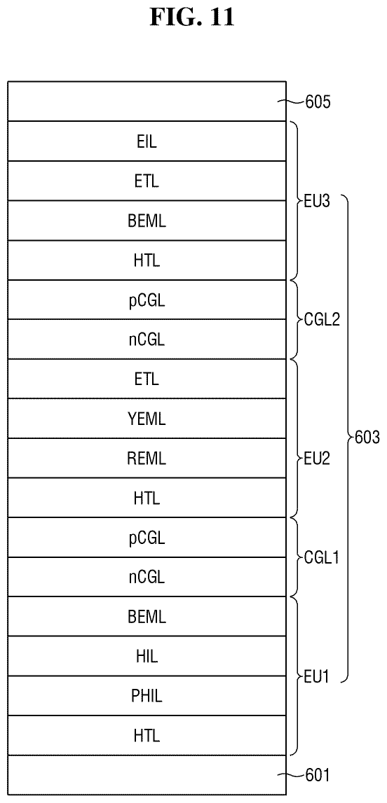

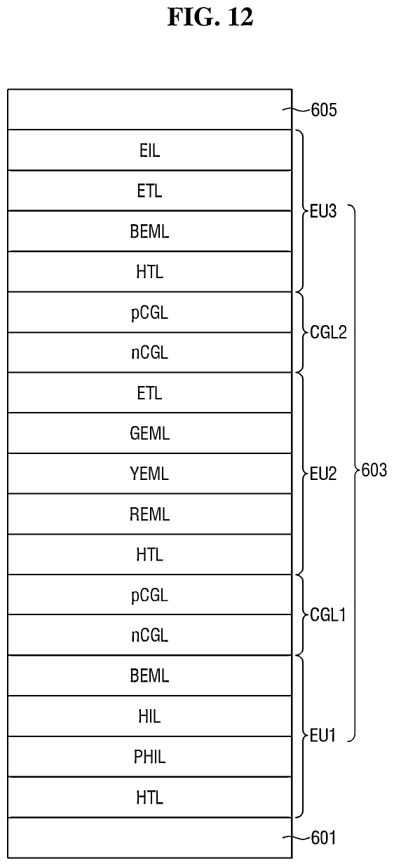

FIG. 11 is a cross-sectional view illustrating an example of an organic light emitting diode of FIG. 9. FIG. 12 is a cross-sectional view illustrating an example of an organic light emitting diode of FIG. 10.

Referring to FIG. 11, the light emitting element LEL (e.g., the organic light emitting diode) may include a first light emitting unit EU1, a second light emitting unit EU2, and a third light emitting unit EU3 that are sequentially stacked. A first charge generation layer CGL1 may be disposed between the first light emitting unit EU1 and the second light emitting unit EU2, and a second charge generation layer CGL2 may be disposed between the second light emitting unit EU2 and the third light emitting unit EU3. Each of the first charge generation layer CGL1 and the second charge generation layer CGL2 may include a negative charge generation layer nCGL and a positive charge generation layer pCGL.

The first light emitting unit EU1 may include a blue light emitting layer BEML. The first light emitting unit EU1 may further include a hole injection layer HIL and a hole transport layer HTL between the pixel electrode 601 and the blue light emitting layer BEML. In an embodiment, a p-doped layer PHIL may be further included between the hole injection layer HIL and the hole transport layer HTL. The p-doped layer PHIL may be formed by doping the hole injection layer HIL with a p-type doping material. In an embodiment, at least one of a blue light auxiliary layer, an electron blocking layer, and a buffer layer may be further included between the blue light emitting layer BEML and the hole transport layer HTL. The blue light auxiliary layer may increase emission efficiency of the blue light emitting layer BEML. The blue light auxiliary layer may increase emission efficiency of the blue light emitting layer BEML by adjusting hole charge balance. The electron blocking layer may prevent injection of electrons into the hole transport layer HTL. The buffer layer may compensate for a resonance distance according to a wavelength of light emitted from the light emitting layer.

The second light emitting unit EU2 may include a yellow light emitting layer YEML and a red light emitting layer REML in direct contact with the yellow light emitting layer YEML below the yellow light emitting layer YEML. The second light emitting unit EU2 may further include a hole transport layer HTL between the positive charge generation layer pCGL of the first charge generation layer CGL1 and the red light emitting layer REML, and may further include an electron transport layer ETL between the yellow light emitting layer YEML and the negative charge generation layer nCGL of the second charge generation layer CGL2.

The third light emitting unit EU3 may include a blue light emitting layer BEML. The third light emitting unit EU3 may further include a hole transport layer HTL between the positive charge generation layer pCGL of the second charge generation layer CGL2 and the blue light emitting layer BEML. The third light emitting unit EU3 may further include an electron transport layer ETL and an electron injection layer EIL between the blue light emitting layer BEML and the common electrode 605. The electron transport layer ETL may be a single layer or multiple layers. In an embodiment, at least one of a blue light auxiliary layer, an electron blocking layer, and a buffer layer may be further included between the blue light emitting layer BEML and the hole transport layer HTL. At least one of a hole blocking layer and a buffer layer may be further included between the blue light emitting layer BEML and the electron transport layer ETL. The hole blocking layer may prevent injection of holes into the electron transport layer ETL.

The light emitting element LEL (e.g., the organic light emitting diode) illustrated in FIG. 12 is different from the light emitting element LEL (e.g., the organic light emitting diode) illustrated in FIG. 11 in a stacked structure of the second light emitting unit EU2, and is the same as the light emitting element (e.g., the organic light emitting diode) illustrated in FIG. 11 in other configurations. Referring to FIG. 12, the second light emitting unit EU2 may include a yellow light emitting layer YEML, a red light emitting layer REML in direct contact with the yellow light emitting layer YEML below the yellow light emitting layer YEML, and a green light emitting layer GEML in direct contact with the yellow light emitting layer YEML above the yellow light emitting layer YEML. The second light emitting unit EU2 may further include a hole transport layer HTL between the positive charge generation layer pCGL of the first charge generation layer CGL1 and the red light emitting layer REML, and may further include an electron transport layer ETL between the green light emitting layer GEML and the negative charge generation layer nCGL of the second charge generation layer CGL2.

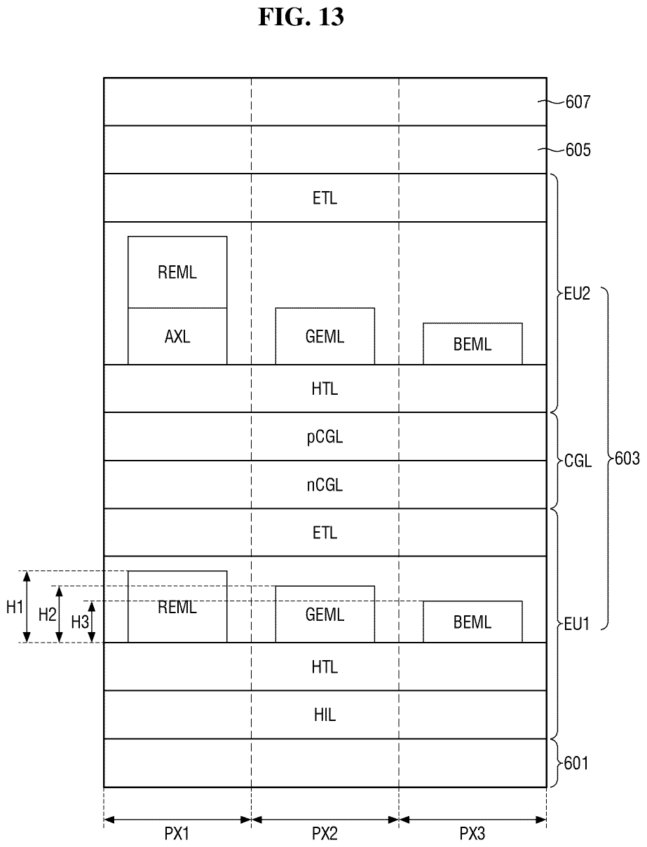

FIG. 13 is a cross-sectional view illustrating a structure of a pixel of a display device according to an embodiment.

Referring to FIG. 13, a display panel 100 of the display device 10 may include a plurality of pixels (e.g., the sub-pixels described above). The plurality of pixels may include a first pixel PX1, a second pixel PX2, and a third pixel PX3. Each of the first pixel PX1, the second pixel PX2, and the third pixel PX3 may include the pixel electrode 601, the common electrode 605, and the intermediate layer 603. In one embodiment, the first pixel PX1 may be a red pixel, the second pixel PX2 may be a green pixel, and the third pixel PX3 may be a blue pixel.

The pixel electrode 601 may be independently provided in each of the first pixel PX1, the second pixel PX2, and the third pixel PX3.

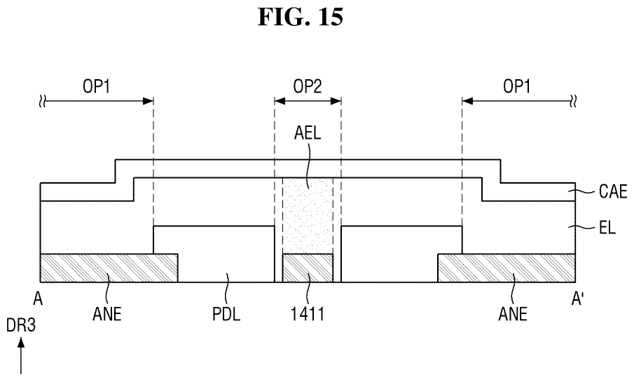

The intermediate layer 603 of each of the first pixel PX1, the second pixel PX2, and the third pixel PX3 may include the first light emitting unit EU1 and the second light emitting unit EU2 that are sequentially stacked, and the charge generation layer CGL between the first light emitting unit EU1 and the second light emitting unit EU2. The charge generation layer CGL may include the negative charge generation layer nCGL and the positive charge generation layer pCGL. The charge generation layer CGL may be a common layer commonly stacked in the first pixel PX1, the second pixel PX2, and the third pixel PX3 and interconnected with each other. Such charge generation layer CGL may be a common layer and may cause leakage current between adjacent pixels. Accordingly, as will be described later with reference to FIGS. 14 to 20, the inventive concept arranges an aging wiring 1410 between adjacent pixels, and uses the aging wiring 1410 to age a portion of the charge generation layer CGL positioned between the adjacent pixels. The aged charge generation layer CGL changes its shape and its resistance increases. Accordingly, the charge generation layer CGL is commonly stacked on the first pixel PX1, the second pixel PX2, and the third pixel PX3 and connected to each other, but leakage current can be blocked by including the aged portion AEL in FIG. 15.

The first light emitting unit EU1 of the first pixel PX1 may include the hole injection layer HIL, the hole transport layer HTL, the red light emitting layer REML, and the electron transport layer ETL sequentially stacked on the pixel electrode 601. The first light emitting unit EU1 of the second pixel PX2 may include the hole injection layer HIL, the hole transport layer HTL, the green light emitting layer GEML, and the electron transport layer ETL sequentially stacked on the pixel electrode 601. The first light emitting unit EU1 of the third pixel PX3 may include the hole injection layer HIL, the hole transport layer HTL, the blue light emitting layer BEML, and the electron transport layer ETL sequentially stacked on the pixel electrode 601. The hole injection layer HIL, the hole transport layer HTL, and the electron transport layer ETL of the first light emitting units EU1 may be commonly stacked and may be a common layer connected to each other. At least in some layers among these common layers (e.g., layers HIL, HTL, ETL) may be aged like the charge generation layer CGL using the aging wiring 1410. The at least some of the aged common layers may be commonly stacked on the first pixel PX1, the second pixel PX2 and the third pixel PX3 and connected to each other, but include the aged portion AEL, thereby blocking the leakage current.

The second light emitting unit EU2 of the first pixel PX1 may include the hole transport layer HTL, an auxiliary layer AXL, the red light emitting layer REML, and the electron transport layer ETL sequentially stacked on the charge generation layer CGL. The second light emitting unit EU2 of the second pixel PX2 may include the hole transport layer HTL, the green light emitting layer GEML, and the electron transport layer ETL sequentially stacked on the charge generation layer CGL. The second light emitting unit EU2 of the third pixel PX3 may include the hole transport layer HTL, the blue light emitting layer BEML, and the electron transport layer ETL sequentially stacked on the charge generation layer CGL. Each of the hole transport layer HTL and the electron transport layer ETL of the second light emitting units EU2 may be commonly stacked in the first pixel PX1, the second pixel PX2, and the third pixel PX3 and may be a common layer connected to each other. In an embodiment, at least one of the hole blocking layer and the buffer layer may be further included between the light emitting layer and the electron transport layer ETL in the second light emitting unit EU2 of the first pixel PX1, the second pixel PX2, and the third pixel PX3. At least in some layers among these common layers (e.g., layers HIL, HTL, ETL), a portion of the charge generation layer CGL positioned between adjacent pixels may be aged like the charge generation layer CGL using the aging wiring 1410. The at least some of the aged common layers may be commonly stacked on the first pixel PX1, the second pixel PX2 and the third pixel PX3 and connected to each other, but include the aged portion AEL, thereby blocking the leakage current.

A thickness H1 of the red light emitting layer REML, a thickness H2 of the green light emitting layer GEML, and a thickness H3 of the blue light emitting layer BEML may be determined according to the resonance distance. The auxiliary layer AXL may be a layer added to adjust the resonance distance, and may include a resonance auxiliary material. For example, the auxiliary layer AXL may include the same material as the hole transport layer HTL.

In FIG. 13, the auxiliary layer AXL may be disposed only in the first pixel PX1, but the embodiment of the present disclosure is not limited thereto. For example, the auxiliary layer AXL may be disposed in at least one of the first pixel PX1, the second pixel PX2, or the third pixel PX3 to adjust the resonance distance of each of the first pixel PX1, the second pixel PX2, and the third pixel PX3.

According to an embodiment, the display panel 110 may further include a capping layer 607 disposed outside the common electrode 605. The capping layer 607 may serve to improve luminous efficiency by the principle of constructive interference. Accordingly, the light extraction efficiency of the light emitting element LEL (e.g., an organic light emitting diode) may be increased, so that the luminous efficiency of the light emitting element LEL (e.g., an organic light emitting diode) may be improved.

FIG. 14 is a plan view schematically illustrating a portion of a pixel of a display panel according to an embodiment. FIG. 15 is a diagram illustrating a portion of a cross-section of a display panel taken along line A-A′ of FIG. 14. For example, FIG. 15 illustrates a portion of the light emitting element layer 503 of the display panel 110 described with reference to FIG. 5. Accordingly, it should be understood that the upper and lower portions of the components illustrated in FIG. 15 are further provided with the layers described with reference to FIG. 5. In FIG. 15, the light emitting layer EL may refer to the intermediate layer 603 described with reference to FIGS. 6 to 13.

Referring to FIGS. 14 and 15, the display panel 110 according to an embodiment includes a pixel defining film PDL that divides a plurality of pixels including the first pixel PX1, the second pixel PX2, and the third pixel PX3. In the pixel defining film PDL disposed between adjacent (that is, adjacent to each other) pixels, the aging wiring 1410 for aging some conductive layers corresponding to a common layer among an EL layer (e.g., the light emitting layers 503 in FIG. 5.) disposed between the pixel electrode ANE (e.g., anode electrode) and the common electrode CAE (e.g., cathode electrode) is disposed. Here, the common layers aged by the aging wiring 1410 refer to at least one layer among the charge generation layer CGL, the hole injection layer HIL, the hole transport layer HTL, and the electron transport layer ETL and/or P-doped layer PHIL described with reference to FIGS. 6 to 13.

According to an embodiment, the aging wiring 1410 may be disposed in a portion of the pixel defining film PDL positioned between adjacent (that is, adjacent to each other) pixels, and may be disposed in a mesh shape. For example, the aging wiring 1410 includes a first aging wiring 1411 arranged to extend in the second direction DR2, and a second aging wiring 1412 arranged to extend in the first direction DR1 perpendicular to the second direction DR2. The first aging wiring 1411 and the second aging wiring 1412 may be formed on the same layer. The first aging wiring 1411 is arranged to cross between each column of a plurality of pixels in the second direction DR2. The second aging wiring 1412 is arranged to cross between each row of a plurality of pixels in the first direction DR1.

According to an embodiment, the aging wiring 1410 may be formed on the same layer as the pixel electrode ANE of each of the plurality of pixels. For example, the material of the aging wiring 1410 may be the same as the material of the pixel electrode ANE.

According to an embodiment, when viewed in a cross section of the display panel, the aging wiring 1410 is disposed to face the common electrode CAE. Accordingly, when power is applied to the aging wiring 1410, a vertical electric field is formed between the aging wiring 1410 and the common electrode CAE, and the electric field ages the common layer around the aging wiring 1410. Here, aging the common layer means damaging some of the conductive layers included in the common layer to change its shape and intentionally increase the resistance of the corresponding area.

According to an embodiment, the aging process in respect to the common layer using the aging wiring 1410 is performed after manufacturing the display panel is completed. During the aging process, a designated voltage is applied to the aging wiring 1410. The designated voltage may be approximately 50V, but the inventive concept is not necessarily limited thereto. When the designated voltage is applied to the aging wiring 1410, a vertical electric field is formed between the aging wiring 1410 and the common electrode CAE, and some conductive layers corresponding to the common layer among the EL layers are aged by the vertical electric field. A portion of the aged conductive layer changes its shape and its resistance increases. Accordingly, the common layer may be commonly stacked on the first pixel PX1, the second pixel PX2, and the third pixel PX3 and connected to each other, but may block leakage current by including the aged portion AEL.

According to an embodiment, the aging wiring 1410 may be disposed in an opening of the pixel defining film PDL. For example, the display panel includes the pixel defining film PDL for partitioning a plurality of pixels, and the pixel defining film PDL includes first openings OP1 corresponding to each of the plurality of pixels. The pixel electrode ANE of each of the plurality of pixels may be disposed in each of the first openings OP1. In addition, the pixel defining film PDL includes second openings OP2 arranged to cross between each column of the plurality of pixels in the second direction DR2 and third openings OP3 arranged to cross between each row of the plurality of pixels in the first direction DR1. A mesh-shaped aging wiring 1410 may be disposed in each of the second opening OP2 and the third opening OP3. For example, the first aging wiring 1411 is disposed in the second opening OP2 to cross between each column of the plurality of pixels in the second direction DR2. The second aging wiring 1412 is disposed in the third opening OP3 to cross between each row of the plurality of pixels in the first direction DR1.

According to an embodiment, the aging wiring 1410 receives an aging signal of a designated voltage through the aging pad 1420 disposed in the non-display area. The aging pad 1420 may be electrically connected to the aging wiring 1410 through an aging signal supply wiring, or may be directly connected to the aging wiring 1410.

In the case of an embodiment in which the aging wiring 1410 and the aging pad 1420 are directly connected, the aging wiring 1410 may have a mesh shape, but a portion thereof may extend to the non-display area outside the display area and may be connected to the aging pad 1420.

In the case of an embodiment provided with an aging signal supply wiring (not illustrated) connecting the aging wiring 1410 and the aging pad 1420, the aging signal supply wiring may be connected to the wiring layer 502 located below the light emitting element layer 503, and the aging wiring 1410 and the aging signal supply wiring may be electrically connected to each other through a contact hole penetrating at least a portion of the wiring layer 502. The aging signal supply wiring may extend to the non-display area outside the display area and be connected to the aging pad 1420.

In FIG. 14, a single aging pad 1420 is illustrated, but the display panel may include a plurality of aging pads 1420 in consideration of the increase in resistance of the aging wiring 1410. The plurality of aging pads 1420 may be arranged at intervals in the non-display area located on one side (e.g., left direction) of the display area to send an aging signal to aging wiring 1410 groups including the aging wirings 1410. Alternatively, the plurality of aging pads 1420 may be disposed in non-display areas located on one side (e.g., left direction) and another side (e.g., right direction) of the display area to supply an aging signal to the aging wirings 1410.

In FIG. 15, the pixel defining film PDL is illustrated as not covering the aging wiring, but the inventive concept is not limited thereto, and portions of both ends of the aging wiring may be covered by the pixel defining film PDL.

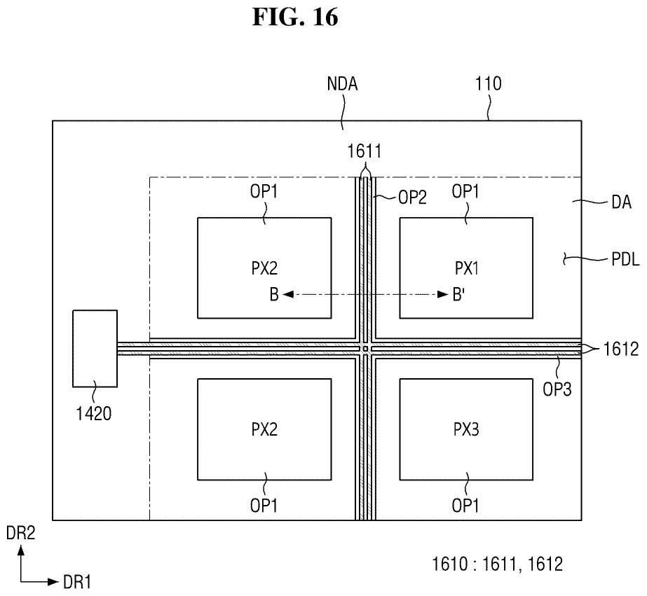

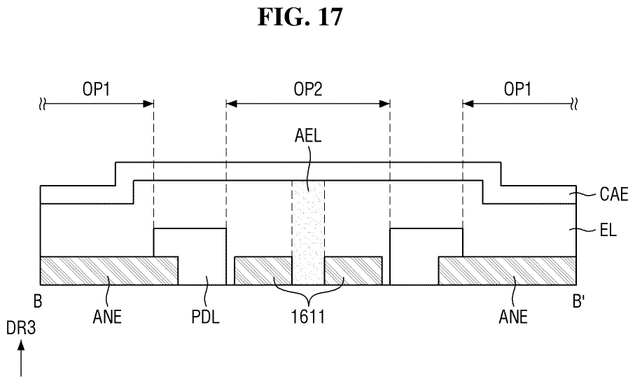

FIG. 16 is a plan view of a display panel illustrating an example in which a pair of aging wirings 1610 is disposed between the pixels. FIG. 17 is a diagram illustrating a portion of a cross-section of a display panel taken along line B-B′ of FIG. 16.

The embodiments of FIGS. 16 and 17 may be at least partially similar to the embodiments of FIGS. 14 and 15. Hereinafter, only the embodiments of FIGS. 16 and 17 different from the embodiments of FIGS. 14 and 15 will be described. Therefore, features not explained in FIGS. 16 and 17 will be replaced with descriptions of the embodiments of FIGS. 14 and 15.

The embodiments of FIGS. 16 and 17 differ from the embodiments of FIGS. 14 and 15 in that the pair of aging wirings 1610 are arranged at intervals between adjacent pixels. For example, a first aging wiring 1611 is disposed in the second opening OP2 to cross between each column of a plurality of pixels in the second direction DR2, but the first aging wiring 1611 is a pair of wirings arranged at intervals from each other. In addition, a second aging wiring 1612 is disposed in the third opening OP3 to cross between each row of the plurality of pixels in the first direction DR1, but the second aging wiring 1612 is a pair of wirings arranged at intervals from each other.

Different voltages may be applied to a pair of aging wires 1610 to form a horizontal electric field between the pair of aging wires 1610. The horizontal electric field ages at least a portion of the common layer positioned around the pair of aging wirings 1610. The voltage applied to each of the pair of aging wirings 1610 may have a voltage difference of, for example, about 50V, but the inventive concept is not necessarily limited thereto.

In FIG. 17, the pixel defining film PDL is illustrated as not covering the aging wiring, but the inventive concept is not limited thereto, and portions of both ends of the aging wiring may be covered by the pixel defining film PDL.

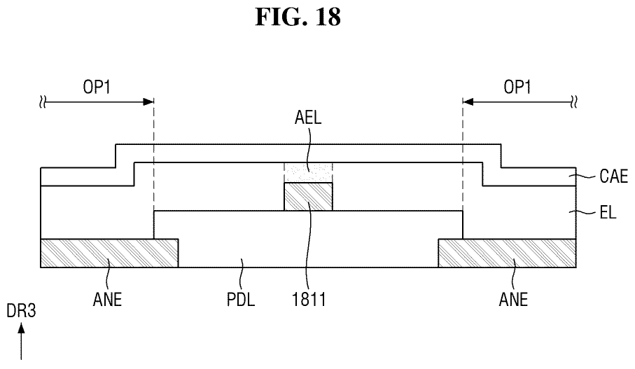

FIG. 18 is a plan view of a display panel illustrating an example in which an aging wiring 1811 is disposed on a pixel defining film.

Referring to FIG. 18, the aging wiring 1811 according to an embodiment may be disposed on the pixel defining film PDL. For example, in the embodiment of FIG. 18, unlike the embodiments of FIGS. 14 to 16, the pixel defining film PDL does not include a second opening OP2 and a third opening OP3, and an aging wiring 1811 is disposed on the pixel defining film PDL. In the case of the embodiment of FIG. 18, the aging wiring 1811 may be electrically connected to an aging signal supply wiring (not illustrated) through a contact hole (not illustrated) penetrating at least a portion of the pixel defining film PDL and the wiring layer 502.

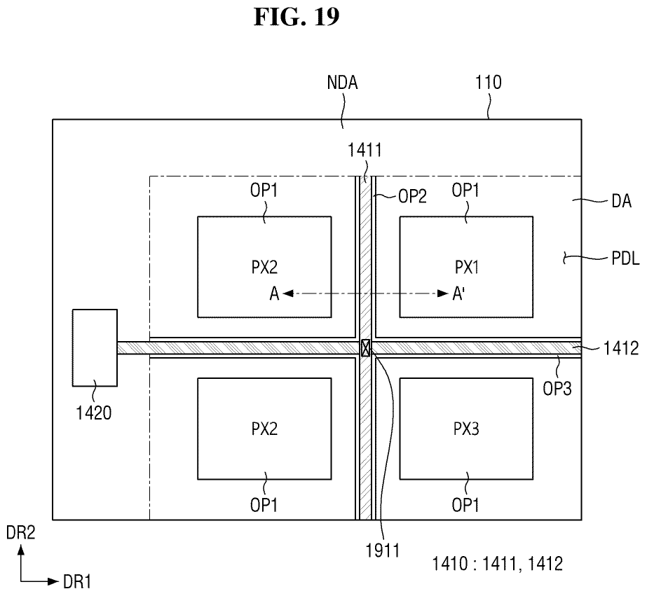

FIG. 19 is a plan view of a display panel illustrating an example in which an aging wiring 1410 is not formed in a mesh structure.

The embodiment of FIG. 19 may be at least partially similar to the embodiments of FIGS. 14 and 15. Hereinafter, only the embodiment of FIG. 19 that is different from the embodiments of FIGS. 14 and 15 will be described. Therefore, features not explained in FIG. 19 will be replaced with descriptions of the embodiments of FIGS. 14 and 15.

In the embodiment of FIG. 19, unlike the embodiments of FIGS. 14 and 15, the aging wiring 1410 may not be formed in a mesh shape, but may be arranged to cross each other between adjacent pixels. For example, the aging wiring 1410 includes a first aging wiring 1411 arranged to cross between each column of the plurality of pixels in the second direction DR2, and a second aging wiring 1412 arranged to cross between each row of the plurality of pixels in the first direction DR1, The first aging wiring 1411 and the second aging wire 1412 may be disposed on different layers, and cross each other between adjacent pixels, but may be electrically connected to each other through a contact hole 1911.

According to an embodiment, the first aging wiring 1411 may be disposed on a different layer from the pixel electrode ANE, and the second aging wiring 1412 may be disposed on the same layer as the pixel electrode ANE. For example, the first aging wiring 1411 may be disposed on at least a portion of the wiring layer 502. Meanwhile, unlike the above example, the second aging wiring 1412 may be placed on the same layer as the pixel electrode ANE, and the first aging wiring 1411 may be placed on a different layer from the pixel electrode ANE.

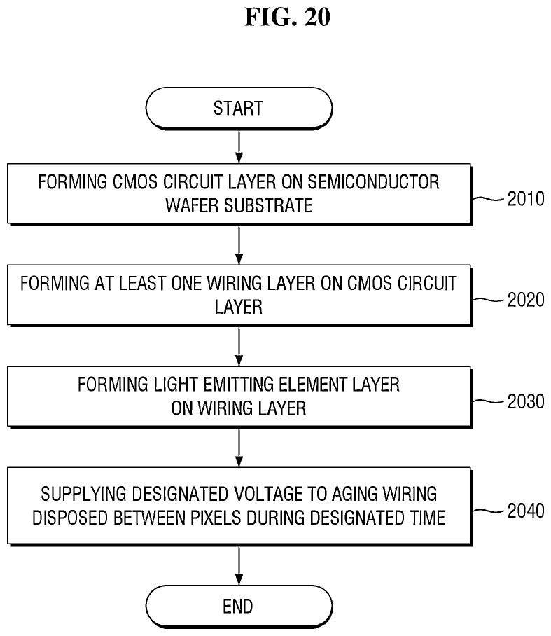

FIG. 20 is a flowchart illustrating a method of manufacturing a display device according to an embodiment.

At least some of the steps of the manufacturing process illustrated in FIG. 20 may be omitted. Before or after each of the steps of the manufacturing process illustrated in FIG. 20, a manufacturing process of a display device that is described or known with reference to this document may be additionally performed.

Hereinafter, a method of manufacturing a display device according to an embodiment will be described with reference to FIG. 20.

In step 2010, a semiconductor wafer substrate 200 may be prepared, and a CMOS layer (e.g., MOSFET layer 501 in FIG. 5) may be formed on the semiconductor wafer substrate. The CMOS layer includes an N-type MOSFET and/or a P-type MOSFET. The first type impurity may be a P-type impurity, and the second type impurity may be an N-type impurity. Alternatively, the first type impurity may be an N-type impurity and the second type impurity may be a P-type impurity. MOSFETs MOS in the CMOS layer constitute the display driving circuit 210 and the pixel driving circuit PC.

In step 2020, a wiring process may be performed to form at least one insulating layer and wirings on the CMOS layer. At least one wiring layer 502 may include insulating layers VIA sequentially stacked on the MOSFET layer 501, and a wiring (not illustrated) and an electrode CE connected to MOSFET MOS through contact holes CT1 penetrating at least a portion of the insulating layers VIA.

The wiring layer 502 may include pad electrodes PD1, PD2, PD3, PD4, PD5, PD6, and PD7 disposed to correspond to the non-display area NDA. The pad electrodes PD1, PD2, PD3, PD4, PD5, PD6, and PD7 may include a first gate pad PD1 to which the first gate line GWL is connected, a second gate pad PD2 to which the second gate line GIL is connected, an initialization pad PD3 to which the initialization line VIL is connected, a light emitting pad PD4 to which the emission control line EML is connected, a data pad PD5 to which the data line DL is connected, a first driving voltage pad PD6 to which the first driving voltage line VDL is connected, and a second driving voltage pad PD7 to which the second driving voltage line VSL is connected. However, the pad electrodes PD1, PD2, PD3, PD4, PD5, PD6, and PD7 illustrated in FIG. 5 are only examples, and the present disclosure is not limited thereto. For example, the wiring layer 502 may further include an aging pad 1420 connected to an aging signal supply wiring (not illustrated) or an aging wiring 1410 in the non-display area NDA. The aging pad 1420 may be electrically connected to the aging wiring 1410 through an aging signal supply wiring, or may be directly connected to the aging wiring 1410.

In step 2030, the light emitting element layer 503 may be formed on the wiring layer 502. The light emitting element layer 503 may further include a pixel defining film PDL that partitions each of the plurality of pixels PX. Each of the plurality of pixels PX includes a pixel electrode ANE, a light emitting layer EL disposed on the pixel electrode ANE, and a common electrode CAE disposed on the light emitting layer EL.

The light emitting layer EL is an intermediate layer 603 disposed between the pixel electrode ANE and the common electrode CAE and may include a polymer or low-molecular organic material that emits light of a predetermined color. The intermediate layer 603 may further include a metal-containing compound such as an organometallic compound, an inorganic material such as quantum dots, and the like, in addition to various organic materials.

The intermediate layer 603 includes at least one common layer commonly stacked on the first pixel PX1, the second pixel PX2, and the third pixel PX3 and connected to each other. The common layer means at least one layer among the charge generation layer CGL, the hole injection layer HIL, the hole transport layer HTL and the electron transport layer ETL, and/or the P-doped layer PHIL, which are described with reference to FIGS. 6 to 13.

In step 2040, an aging process in which a designated voltage is supplied to the aging wiring 1410 disposed between the adjacent pixels during designated time may be performed. According to an embodiment, the aging process in respect to the common layer using the aging wiring 1410 is performed after manufacturing the display panel is completed. During the aging process, a designated voltage is applied to the aging wiring 1410. The designated voltage may be approximately 50V, but the inventive concept is not necessarily limited thereto. When the designated voltage is applied to the aging wiring 1410, a vertical electric field is formed between the aging wiring 1410 and the common electrode CAE, and some conductive layers corresponding to the common layer among the EL layers are aged by the vertical electric field. A portion of the aged conductive layer changes its shape and its resistance increases. Accordingly, the common layer may be commonly stacked on the first pixel PX1, the second pixel PX2, and the third pixel PX3 and connected to each other, but may block leakage current by including the aged portion AEL.

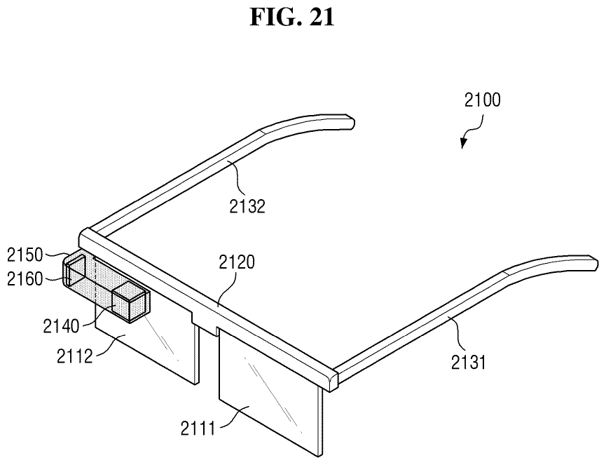

FIG. 21 is an example view of a VR device 2100 including a display device 10 according to an embodiment.

The display device 10 according to an embodiment may be included in a mobile electronic device. The display device 10 according to an embodiment may be included in a wearable device that is developed in the form of glasses or a helmet and forms a focus at a short distance from a user's eyes. For example, the wearable device may be an HMD or augmented reality (AR) glasses. Such a wearable device provides an AR screen or a virtual reality (VR) screen to a user.

FIG. 21 illustrates the VR device 2100 to which a display device 2160 according to an embodiment has been applied. Here, the display device 2160 may include the elements of FIGS. 1 through 19 described above.

Referring to FIG. 21, the VR device 2100 according to an embodiment may be an AR glasses in the form of glasses. The VR device 2100 according to an embodiment may include the display device 2160, a left lens 2111, a right lens 2112, a support frame 2120, eyeglass frame legs 2131 and 2132, a reflective member 2140, and an accommodating unit 2150.

Although the VR device 2100 in an AR glasses form is exemplified in FIG. 21, the VR device 2100 according to an embodiment may be applied to an HMD. That is, the VR device 2100 according to an embodiment is not limited to that shown in FIG. 21, and can be applied in various forms to various other mobile electronic devices.

The accommodating unit 2150 may include the display device 2160 and the reflective member 2140. An image displayed on the display device 2160 may be reflected by the reflective member 2140 and provided to a user's right eye through the right lens 2112. Accordingly, the user may view a VR image displayed on the display device 2160 through the right eye.

Although the accommodating unit 2150 is disposed at a right end of the support frame 2120 in FIG. 21, the present disclosure is not limited thereto. For example, the accommodating unit 2150 may also be disposed at a left end of the support frame 2120. In this case, an image displayed on the display device 2160 may be reflected by the reflective member 2140 and provided to the user's left eye through the left lens 2111. Accordingly, the user may view a VR image displayed on the display device 2160 through the left eye. Alternatively, the accommodating unit 2150 may be disposed at both the right end and the left end of the support frame 2120. In this case, the user may view a VR image displayed on the display device 2160 through both the left eye and the right eye.

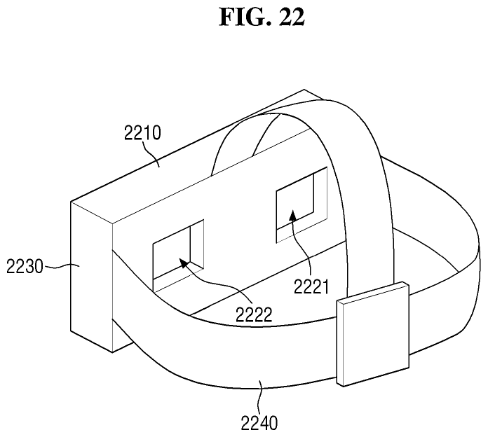

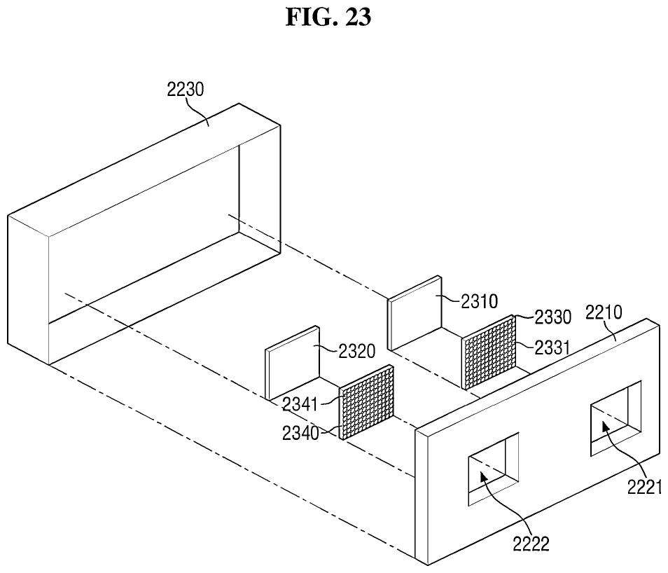

FIGS. 22 and 23 are exemplary views illustrating an HMD device to which the display device according to an embodiment is applied.

Referring to FIGS. 22 and 23, the display device 10 according to an embodiment may be applied to an HMD device. The HMD device includes a first display device 2310 and a second display device 2320, each of which may be the display device 10 according to an embodiment. The first display device 2310 provides an image to the user's right eye, and the second display device 2320 provides an image to the user's left eye.

A first lens array 2330 may be disposed between the first display device 2310 and an accommodating unit cover 2210. The first lens array 2330 may include a plurality of lenses 2331. The plurality of lenses 2331 may be formed as convex lenses that are convex in a direction of the accommodating unit cover 2210.

A second lens array 2340 may be disposed between the second display device 2320 and the accommodating unit cover 2210. The second lens array 2340 may include a plurality of lenses 2341. The plurality of lenses 2341 may be formed as convex lenses that are convex in a direction of the accommodating unit cover 2210.

An accommodating unit 2230 serves to accommodate the first display device 2310, the second display device 2320, the first lens array 2330, and the second lens array 2340. In order to accommodate the first display device 2310, the second display device 2320, the first lens array 2330, and the second lens array 2340, one surface of the accommodating unit 2230 may be opened.

The accommodating unit cover 2210 is disposed to cover the opened surface of the accommodating unit 2230. The accommodating unit cover 2210 may include a first opening 2221 where the user's right eye is disposed and a second opening 2222 where the user's left eye is disposed. It is illustrated in FIGS. 22 and 23 that the first opening 2221 and the second opening 2222 are formed in a quadrangular shape, but the present disclosure is not limited thereto. The first opening 2221 and the second opening 2222 may be formed in a circular shape or an elliptical shape. Alternatively, the first opening 2221 and the second opening 2222 may be combined to form one opening.

The first opening 2221 may be aligned with the first display device 2310 and the first lens array 2330, and the second opening 2222 may be aligned with the second display device 2320 and the second lens array 2340. Therefore, the user may view the image of the first display device 2310 magnified as a virtual image by the first lens array 2330 through the first opening 2221, and may view the image of the second display device 2320 magnified as a virtual image by the second lens array 2340 through the second opening 2222.

A head mounting band 2240 serves to fix the accommodating portion 2230 to a user's head so that the first opening 2221 and the second opening 2222 of the accommodating unit cover 2210 are disposed on the user's right and left eyes, respectively. The head mounting band 2240 may be connected to upper, left side, and right side surfaces of the accommodating unit 2230.

In concluding the detailed description, those skilled in the art will appreciate that many variations and modifications can be made to the embodiments without substantially departing from the principles of the inventive concept. Therefore, the disclosed embodiments of the inventive concept are used in a generic and descriptive sense only and not for purposes of limitation.

What is claimed is:

1. A display device comprising:
a semiconductor wafer substrate;
a complementary metal oxide semiconductor (CMOS) circuit layer disposed on the semiconductor wafer substrate; and
a light emitting element layer disposed on the CMOS circuit layer,
wherein the light emitting element layer comprises:
a pixel defining film partitioning a plurality of pixels;
a pixel electrode disposed independently in each of the plurality of pixels;
an aging wiring disposed between the plurality of pixels;
a light emitting layer commonly covering the pixel electrodes of each of the plurality of pixels and the aging wiring; and
a common electrode covering the light emitting layer,
wherein a portion positioned between the aging wiring and the common electrode of the light emitting layer comprises an aged portion in which at least a portion of a conductive layer included in the light emitting layer is aged.

2. The display device of claim 1,
wherein the aged portion of the light emitting layer has a higher resistance of the conductive layer compared to other portions of the light emitting layer.

3. The display device of claim 1,
wherein the pixel defining film comprises:
a first opening in which the pixel electrode is disposed; and
a second opening and a third opening in which the aging wiring is disposed.

4. The display device of claim 3,
wherein the aging wiring comprises:
a first aging wiring disposed in the second opening to cross between each column of the plurality of pixels; and
a second aging wiring disposed in the third opening to cross between each row of the plurality of pixels.

5. The display device of claim 4,
wherein the aging wiring has a mesh shape in which the first aging wiring and the second aging wiring are on the same layer.

6. The display device of claim 5,
wherein the first aging wiring and the second aging wiring are disposed on a same layer as the pixel electrode.

7. The display device of claim 4,
wherein the first aging wiring and the second aging wiring are disposed on different layers.

8. The display device of claim 7,
wherein the first aging wiring is disposed on a different layer from the pixel electrode, and
wherein the second aging wiring is disposed on a same layer as the pixel electrode.

9. The display device of claim 4,
wherein each of the first aging wiring and the second aging wiring comprises a pair of wirings arranged at intervals from each other between adjacent pixels.

10. The display device of claim 1,
wherein at least some conductive layers included in the light emitting layer comprises at least one layer among a charge generation layer, a hole injection layer, a hole transport layer, an electron transport layer, and a p-doped layer.

11. A method of manufacturing a display device comprising:
forming a complementary metal oxide semiconductor (CMOS) circuit layer on a semiconductor wafer substrate;
forming a light emitting element layer comprising a pixel electrode, a light emitting layer, and a common electrode on the CMOS circuit layer; and
aging at least some conductive layers included in the light emitting layer by supplying a designated voltage to an aging wiring disposed between a plurality of pixels during a designated time,
wherein the at least some conductive layers have an increased resistance due to the aging between the plurality of pixels.

12. The method of claim 11,
wherein the forming of the light emitting element layer comprises forming a pixel defining film partitioning the plurality of pixels,
wherein the pixel defining film comprises:
a first opening in which the pixel electrode is disposed; and
a second opening and a third opening in which the aging wiring is disposed.

13. The method of claim 12,
wherein the aging wiring comprises:
a first aging wiring disposed in the second opening to cross between each column of the plurality of pixels; and
a second aging wiring disposed in the third opening to cross between each row of the plurality of pixels.

14. The method of claim 13,
wherein the aging wiring has a mesh shape in which the first aging wiring and the second aging wiring are formed on a same layer.

15. The method of claim 14,
further comprising forming the first aging wiring and the second aging wiring on a same layer as the pixel electrode.

16. The method of claim 13,
wherein the first aging wiring and the second aging wiring are disposed on different layers.

17. The method of claim 16,
wherein the first aging wiring is disposed on a different layer from the pixel electrode, and
wherein the second aging wiring is disposed on a same layer as the pixel electrode.

18. The method of claim 13,
wherein each of the first aging wiring and the second aging wiring comprises a pair of wirings arranged at intervals from each other between adjacent pixels.

19. The method of claim 11,
wherein the at least some conductive layers included in the light emitting layer comprises at least one layer among a charge generation layer, a hole injection layer, a hole transport layer, an electron transport layer, and a p-doped layer.

20. The method of claim 11,
wherein the designated voltage supplied to the aging wiring is approximately 50V.
